(19) United States
(12) Patent Application Publication
(10) Pub. No.: US 2026/0197941 A1
(43) Pub. Date: Jul. 9, 2026

(54) COIL DEVICE

(71) Applicant: SUMITOMO ELECTRIC PRINTED CIRCUITS, INC., Shiga (JP)

(72) Inventor: Michi OGATA, Shiga (JP)

(73) Assignee: SUMITOMO ELECTRIC PRINTED CIRCUITS, INC., Shiga (JP)

(21) Appl. No.: 19/131,706

(22) PCT Filed: Nov. 16, 2023
(86) PCT No.: PCT/JP2023/041284

§ 371 Date: May 21, 2025

(30) Foreign Application Priority Data
Nov. 28, 2022 (JP) 2022-189240

(51) Int. Cl. H05K 1/11; H01F 5/00; H01F 7/06; H02K 3/26; H05K 1/14

(52) U.S. Cl. CPC H05K 1/115; H01F 5/003; H05K 1/14; H01F 2007/068; H02K 3/26

(57) ABSTRACT

A coil device includes at least one printed wiring board. Each of the at least one printed wiring board has a first base film having a first main surface and a second main surface opposite to the first main surface, and a first wire disposed on the first main surface. The first wire has a plurality of first coil portions arranged along a first direction in a plan view. Each of the plurality of first coil portions is constituted by the first wire wound spirally in a plan view, and has a first straight portion and a second straight portion, and a first connection portion and a second connection portion. In a plan view, the first wire at the first straight portion and the first wire at the second straight portion extend along a second direction orthogonal to the first direction.

### TECHNICAL FIELD

The present disclosure relates to a coil device. The present application claims priority based on Japanese Patent Application No. 2022-189240 filed on Nov. 28, 2022. The entire contents described in the Japanese Patent Application are incorporated herein by reference.

### BACKGROUND ART

For example, a coil device described in Japanese Patent Laying-Open No. 2020-72551 (PTL 1) is described. The coil device described in PTL 1 has a flexible substrate having a main surface, and a wire. The wire is disposed on the main surface. The wire has a plurality of coils arranged along a first direction in a plan view. Each of the plurality of coils is constituted by winding the wire spirally in a plan view, and has a first straight portion, a second straight portion, a third straight portion, and a fourth straight portion, and a first connection portion and a second connection portion.

One end portion of the first straight portion and one end portion of the third straight portion are connected by the first connection portion. The other end portion of the first straight portion and the other end portion of the third straight portion are connected to one end portion of the second straight portion and one end portion of the fourth straight portion, respectively. The other end portion of the second straight portion and the other end portion of the fourth straight portion are connected by the second connection portion. The wire at the first straight portion, the wire at the second straight portion, the wire at the third straight portion, and the wire at the fourth straight portion extend straight to be inclined with respect to a second direction orthogonal to the first direction in a plan view. An extending direction of the wire at the first straight portion and an extending direction of the wire at the fourth straight portion are parallel to each other. An extending direction of the wire at the second straight portion and an extending direction of the wire at the third straight portion are parallel to each other, and are inclined opposite to the wire at the first straight portion and the wire at the fourth straight portion with respect to the second direction. The wire at the first connection portion and the wire at the second connection portion extend semicircularly in a plan view.

### CITATION LIST

### Patent Literature

PTL 1: Japanese Patent Laying-Open No. 2020-72551

### SUMMARY OF INVENTION

A coil device of the present disclosure includes at least one printed wiring board. Each of the at least one printed wiring board has a first base film having a first main surface and a second main surface opposite to the first main surface, and a first wire disposed on the first main surface. The first wire has a plurality of first coil portions arranged along a first direction in a plan view. Each of the plurality of first coil portions is constituted by the first wire wound spirally in a plan view, and has a first straight portion and a second straight portion, and a first connection portion and a second connection portion. In a plan view, the first wire at the first straight portion and the first wire at the second straight portion extend along a second direction orthogonal to the first direction. The first straight portion has a first end portion and a second end portion which are both end portions in the second direction. The second straight portion has a third end portion and a fourth end portion which are both end portions in the second direction. The first connection portion connects the first end portion and the third end portion. The second connection portion connects the second end portion and the fourth end portion. A sum of a width in the second direction of the first connection portion and a width in the second direction of the second connection portion is smaller than a sum of a width in the first direction of the first straight portion and a width in the first direction of the second straight portion.

### BRIEF DESCRIPTION OF DRAWINGS

FIG. 1 is a first plan view of a coil device 100.

FIG. 2 is a second plan view of coil device 100.

FIG. 3 is a cross sectional view taken along III-III in FIG. 1.

FIG. 4 is a first plan view of coil device 100 according to a first modification.

FIG. 5 is a second plan view of coil device 100 according to the first modification.

FIG. 6 is a diagram of a process for manufacturing coil device 100.

FIG. 7 is a cross sectional view illustrating a preparing step S1.

FIG. 8 is a cross sectional view illustrating a conductive layer forming step S2.

FIG. 9 is a cross sectional view illustrating a resist pattern forming step S3.

FIG. 10 is a cross sectional view illustrating an electrolytic plating step S4.

FIG. 11 is a cross sectional view illustrating a resist pattern removing step S5.

FIG. 12 is a first plan view of a coil device 200.

FIG. 13 is a second plan view of coil device 200.

FIG. 14 is a cross sectional view taken along XIV-XIV in FIG. 12.

FIG. 15 is a cross sectional view of coil device 200 according to a modification.

### DETAILED DESCRIPTION

### Problem to be Solved by the Present Disclosure

In the coil device described in PTL 1, there is room for improvement in thrust generated on a magnet. Further, in the coil device described in PTL 1, a dimension of each coil in the second direction increases.

The present disclosure has been made in view of the problems of the conventional technique as described above. More specifically, the present disclosure provides a coil device that can improve thrust on a magnet and can decrease a dimension.

### Advantageous Effect of the Present Disclosure

According to the coil device of the present disclosure, it is possible to improve thrust on a magnet and to decrease a dimension in a second direction.

### Description of Embodiments of the Present Disclosure

First, embodiments of the present disclosure will be described in list form.
(1) A coil device according to an embodiment includes at least one printed wiring board. Each of the at least one printed wiring board has a first base film having a first main surface and a second main surface opposite to the first main surface, and a first wire disposed on the first main surface. The first wire has a plurality of first coil portions arranged along a first direction in a plan view. Each of the plurality of first coil portions is constituted by the first wire wound spirally in a plan view, and has a first straight portion and a second straight portion, and a first connection portion and a second connection portion. In a plan view, the first wire at the first straight portion and the first wire at the second straight portion extend along a second direction orthogonal to the first direction. The first straight portion has a first end portion and a second end portion which are both end portions in the second direction. The second straight portion has a third end portion and a fourth end portion which are both end portions in the second direction. The first connection portion connects the first end portion and the third end portion. The second connection portion connects the second end portion and the fourth end portion. A sum of a width in the second direction of the first connection portion and a width in the second direction of the second connection portion is smaller than a sum of a width in the first direction of the first straight portion and a width in the first direction of the second straight portion. According to the coil device in (1), it is possible to improve thrust on a magnet and to decrease a dimension in the second direction.
(2) In the coil device in (1), in a plan view, the first wire at the first connection portion and the first wire at the second connection portion may extend along the first direction. According to the coil device in (2), it is possible to further decrease the dimension in the second direction.
(3) In the coil device in (1) or (2), a width in the second direction of the first wire at the first connection portion and a width in the second direction of the first wire at the second connection portion may be smaller than a width in the first direction of the first wire at the first straight portion and a width in the first direction of the first wire at the second straight portion.
(4) In the coil device in (1) to (3), a distance between two portions of the first wire adjacent to each other in the first connection portion and a distance between two portions of the first wire adjacent to each other in the second connection portion may be equal to a distance between two portions of the first wire adjacent to each other in the first straight portion and a distance between two portions of the first wire adjacent to each other in the second straight portion. According to the coil device in (4), the first wire can be easily formed.
(5) In the coil device in (1) to (4), each of the at least one printed wiring board may further have a second wire disposed on the second main surface. The second wire may have a plurality of second coil portions arranged along the first direction in a plan view. Each of the plurality of second coil portions may be constituted by the second wire wound spirally in a plan view, and may have a third straight portion and a fourth straight portion, and a third connection portion and a fourth connection portion. In a plan view, the second wire at the third straight portion and the second wire at the fourth straight portion may extend along the second direction. The third straight portion may have a fifth end portion and a sixth end portion which are both end portions in the second direction. The fourth straight portion may have a seventh end portion and an eighth end portion which are both end portions in the second direction. The third connection portion may connect the fifth end portion and the seventh end portion. The fourth connection portion may connect the sixth end portion and the eighth end portion. A width in the second direction of the third connection portion and a width in the second direction of the fourth connection portion may be smaller than a width in the first direction of the third straight portion and a width in the first direction of the fourth straight portion. According to the coil device in (5), it is possible to further improve the thrust on the magnet.
(6) In the coil device in (1) to (5), the at least one printed wiring board may be a plurality of printed wiring boards.
(7) In the coil device in (6), the plurality of printed wiring boards may include a first printed wiring board and a second printed wiring board overlapping each other. The second main surface of the second printed wiring board may face the first main surface of the first printed wiring board. The first straight portion of the second printed wiring board may overlap the second straight portion of the first printed wiring board in a plan view. According to the coil device in (7), the coils can be disposed closely along the first direction.

### Details of Embodiments of the Present Disclosure

Details of the embodiments of the present disclosure will be described with reference to the drawings. In the drawings below, identical or corresponding parts will be designated by the same reference numerals, and redundant description will not be repeated.

### First Embodiment

Hereinafter, a coil device according to a first embodiment will be described. The coil device according to the first embodiment is referred to as a coil device 100.

### Configuration of Coil Device 100

Hereinafter, a configuration of coil device 100 will be described.

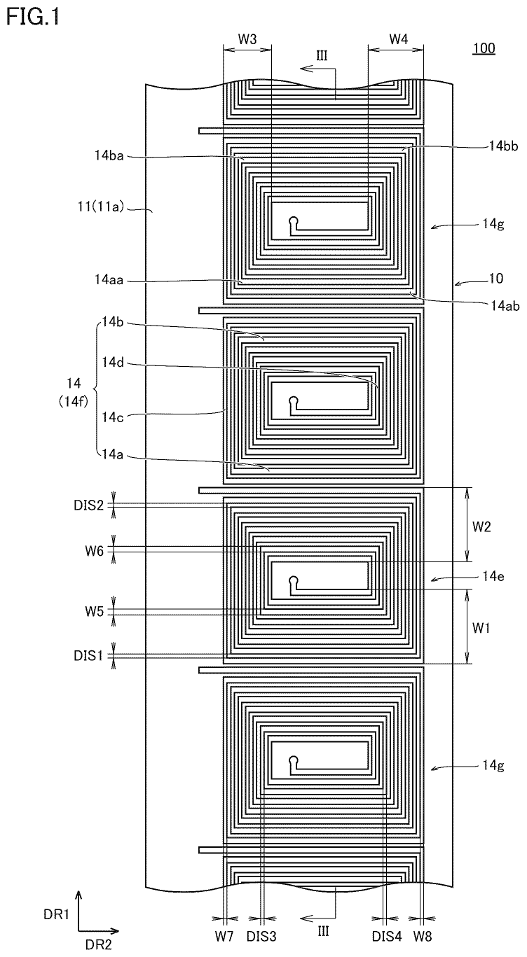

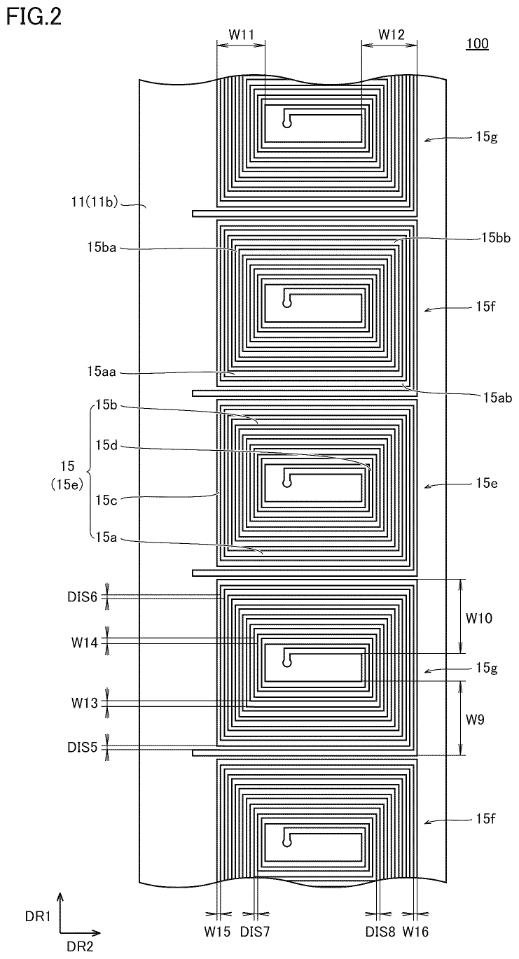

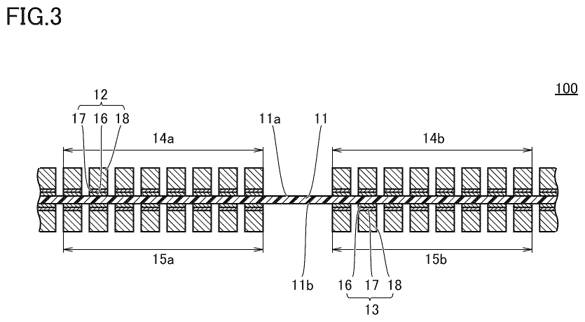

FIG. 1 is a first plan view of coil device 100. FIG. 2 is a second plan view of coil device 100. It should be noted that the direction of viewing the plane of FIG. 2 is the same as that of FIG. 1. FIG. 3 is a cross sectional view taken along III-III in FIG. 1. As shown in FIGS. 1 to 3, coil device 100 has a printed wiring board 10. Printed wiring board 10 has a base film 11, a first wire 12, and a second wire 13.

A constituent material for base film 11 is an electrically insulating material having flexibility. Specific examples of the constituent material for base film 11 include polyimide. Base film 11 has a first main surface 11a and a second main surface 11b. First main surface 11a and second main surface 11b are end surfaces in a thickness direction of base film 11. Second main surface 11b is a surface opposite to first main surface 11a.

First wire 12 is disposed on first main surface 11a. First wire 12 has a plurality of first coils 14. The plurality of first coils 14 are arranged along a first direction DR1 in a plan view. First direction DR1 corresponds to a longitudinal direction of base film 11 in a plan view. First coil 14 is constituted by winding first wire 12 spirally in a plan view.

First coil 14 has a first straight portion 14a, a second straight portion 14b, a first connection portion 14c, and a second connection portion 14d. First wire 12 at first straight portion 14a and first wire 12 at second straight portion 14b extend along a second direction DR2 in a plan view. Second direction DR2 is a direction orthogonal to first direction DR1 in a plan view.

First straight portion 14a has a first end portion 14aa and a second end portion 14ab in second direction DR2. First end portion 14aa and second end portion 14ab are both ends of first straight portion 14a in second direction DR2. Second straight portion 14b has a third end portion 14ba and a fourth end portion 14bb in second direction DR2. Third end portion 14ba and fourth end portion 14bb are both ends of second straight portion 14b in second direction DR2. First end portion 14aa and third end portion 14ba face each other in first direction DR1. Second end portion 14ab and fourth end portion 14bb face each other in first direction DR1.

First wire 12 at first connection portion 14c and first wire 12 at second connection portion 14d preferably extend along first direction DR1 in a plan view. That is, first coil 14 is preferably rectangular in a plan view. First connection portion 14c connects first end portion 14aa and third end portion 14ba. Second connection portion 14d connects second end portion 14ab and fourth end portion 14bb.

A width of first straight portion 14a in first direction DR1 is referred to as a width W1, and a width of second straight portion 14b in first direction DR1 is referred to as a width W2. A width of first connection portion 14c in second direction DR2 is referred to as a width W3, and a width of second connection portion 14d in second direction DR2 is referred to as a width W4. The sum of width W3 and width W4 is smaller than the sum of width W1 and width W2. Each of width W3 and width W4 is preferably smaller than width W1 and smaller than width W2. It should be noted that a width of first coil 14 in second direction DR2 is preferably larger than a width of first coil 14 in first direction DR1.

A width in first direction DR1 of first wire 12 at first straight portion 14a is referred to as a width W5. A width in first direction DR1 of first wire 12 at second straight portion 14b is referred to as a width W6. A width in second direction DR2 of first wire 12 at first connection portion 14c is referred to as a width W7. A width in second direction DR2 of first wire 12 at second connection portion 14d is referred to as a width W8. Width W7 and width W8 are preferably smaller than width W5 and width W6.

A distance between two portions of first wire 12 adjacent to each other in first straight portion 14a is referred to as a distance DIS1, and a distance between two portions of first wire 12 adjacent to each other in second straight portion 14b is referred to as a distance DIS2. A distance between two portions of first wire 12 adjacent to each other in first connection portion 14c is referred to as a distance DIS3, and a distance between two portions of first wire 12 adjacent to each other in second connection portion 14d is referred to as a distance DIS4. Distance DIS1, distance DIS2, distance DIS3, and distance DIS4 are preferably equal to each other.

It should be noted that, when an average value of values measured at 10 positions for one of distance DIS1, distance DIS2, distance DIS3, and distance DIS4 is 0.95 times or more and 1.05 times or less an average value of values measured at 10 positions for another one of distance DIS1, distance DIS2, distance DIS3, and distance DIS4, the one and the other one are considered to be equal to each other.

Second wire 13 is disposed on second main surface 11b. Second wire 13 has a plurality of second coils 15. The plurality of second coils 15 are arranged along first direction DR1 in a plan view. Second coil 15 is constituted by winding second wire 13 spirally in a plan view.

Second coil 15 has a third straight portion 15a, a fourth straight portion 15b, a third connection portion 15c, and a fourth connection portion 15d. Second wire 13 at third straight portion 15a and second wire 13 at fourth straight portion 15b extend along second direction DR2 in a plan view.

Third straight portion 15a has a fifth end portion 15aa and a sixth end portion 15ab in second direction DR2. Fifth end portion 15aa and sixth end portion 15ab are both ends of third straight portion 15a in second direction DR2. Fourth straight portion 15b has a seventh end portion 15ba and an eighth end portion 15bb in second direction DR2. Seventh end portion 15ba and eighth end portion 15bb are both ends of fourth straight portion 15b in second direction DR2. Fifth end portion 15aa and seventh end portion 15ba face each other in first direction DR1. Sixth end portion 15ab and eighth end portion 15bb face each other in first direction DR1.

Second wire 13 at third connection portion 15c and second wire 13 at fourth connection portion 15d preferably extend along first direction DR1 in a plan view. That is, second coil 15 is preferably rectangular in a plan view. Third connection portion 15c connects fifth end portion 15aa and seventh end portion 15ba. Fourth connection portion 15d connects sixth end portion 15ab and eighth end portion 15bb.

A width of third straight portion 15a in first direction DR1 is referred to as a width W9, and a width of fourth straight portion 15b in first direction DR1 is referred to as a width W10. A width of third connection portion 15c in second direction DR2 is referred to as a width W11, and a width of fourth connection portion 15d in second direction DR2 is referred to as a width W12. The sum of width W11 and width W12 is smaller than the sum of width W9 and width W10. Each of width W11 and width W12 is preferably smaller than width W9 and width W10. It should be noted that a width of second coil 15 in second direction DR2 is preferably larger than a width of second coil 15 in first direction DR1.

A width in first direction DR1 of second wire 13 at third straight portion 15a is referred to as a width W13, and a width in first direction DR1 of second wire 13 at fourth straight portion 15b is referred to as a width W14. A width in second direction DR2 of second wire 13 at third connection portion 15c is referred to as a width W15, and a width in second direction DR2 of second wire 13 at fourth connection portion 15d is referred to as a width W16. Width W15 and width W16 are preferably smaller than width W13 and width W14.

A distance between two portions of second wire 13 adjacent to each other in third straight portion 15a is referred to as a distance DIS5, and a distance between two portions of second wire 13 adjacent to each other in fourth straight portion 15b is referred to as a distance DIS6. A distance between two portions of second wire 13 adjacent to each other in third connection portion 15c is referred to as a distance DIS7, and a distance between two portions of second wire 13 adjacent to each other in fourth connection portion 15d is referred to as a distance DIS8. Distance DIS5, distance DIS6, distance DIS7, and distance DIS8 are preferably equal to each other.

It should be noted that, when an average value of values measured at 10 positions for one of distance DIS5, distance DIS6, distance DIS7, and distance DIS8 is 0.95 times or more and 1.05 times or less an average value of values measured at 10 positions for another one of distance DIS5, distance DIS6, distance DIS7, and distance DIS8, the one and the other one are considered to be equal to each other.

The plurality of first coils 14 overlap the plurality of second coils 15, respectively, in a plan view. First coil 14 and second coil 15 overlapping each other in a plan view are electrically connected. More specifically, a land portion at an innermost circumference of first coil 14 is electrically connected to a land portion at an innermost circumference of second coil 15. Thereby, first coil 14 and second coil 15 overlapping each other in a plan view function as one coil.

The plurality of first coils 14 include a plurality of first coils 14e, a plurality of first coils 14 f, and a plurality of first coils 14g. First coil 14 e, first coil 14 f, and first coil 14g are arranged in this order along first direction DR1. The plurality of first coils 14e are electrically connected to each other, the plurality of first coils 14f are electrically connected to each other, and the plurality of first coils 14g are electrically connected to each other.

Base film 11 is rolled into a cylindrical shape along first direction DR1. Thereby, coil device 100 serves as a stator of a motor. On this occasion, currents having phases shifted from each other respectively flow through the plurality of first coils 14e, the plurality of first coils 14f, and the plurality of first coils 14g.

Each of first wire 12 and second wire 13 has, for example, a seed layer 16, a conductive layer 17, and an electrolytic plating layer 18. Seed layer 16 is disposed on each main surface (first main surface 11a, second main surface 11b) of base film 11. A constituent material for seed layer 16 is a nickel-chromium alloy, for example.

Conductive layer 17 is disposed on seed layer 16. Conductive layer 17 is a layer formed by sputtering, for example. A constituent material for conductive layer 17 is copper, for example. Electrolytic plating layer 18 is disposed on conductive layer 17. Electrolytic plating layer 18 is a layer formed by electrolytic plating. A constituent material for electrolytic plating layer 18 is copper, for example.

It should be noted that, although not shown, a through hole 11c is formed in base film 11. Through hole 11c overlaps the land portion at the innermost circumference of first coil 14 and the land portion at the innermost circumference of second coil 15 in a plan view. Conductive layer 17 is also disposed on an inner wall surface of through hole 11c and on a side surface of seed layer 16 contiguous to the inner wall surface of through hole 11c. Thereby, first coil 14 and second coil 15 overlapping each other in a plan view are electrically connected.

### First Modification

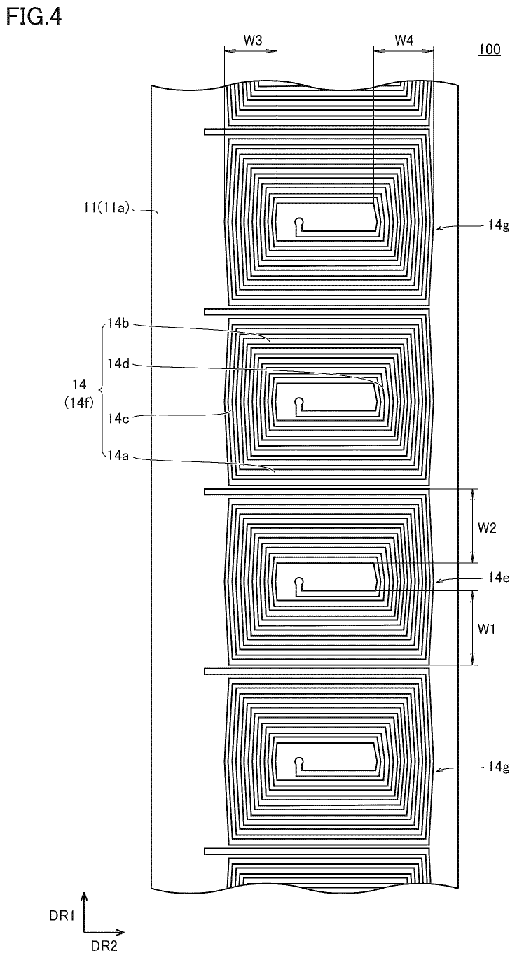

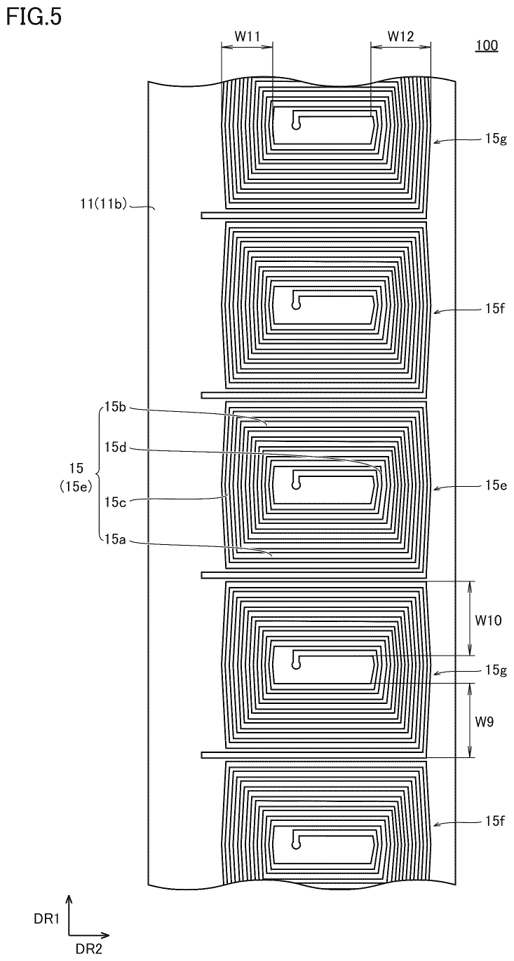

FIG. 4 is a first plan view of coil device 100 according to a first modification. FIG. 5 is a second plan view of coil device 100 according to the first modification. It should be noted that the direction of viewing the plane of FIG. 5 is the same as that of FIG. 4. As shown in FIGS. 4 and 5, as long as the sum of width W3 and width W4 is smaller than the sum of width W1 and width W2, first wire 12 at first connection portion 14c and first wire 12 at second connection portion 14d do not have to extend straight along first direction DR1 in a plan view. Similarly, as long as the sum of width W11 and width W12 is smaller than the sum of width W9 and width W10, second wire 13 at third connection portion 15c and second wire 13 at fourth connection portion 15d do not have to extend straight along first direction DR1 in a plan view.

### Second Modification

Although the case where coil device 100 has both first wire 12 (the plurality of first coils 14) and second wire 13 (the plurality of second coils 15) has been described above, coil device 100 does not have to have one of first wire 12 (the plurality of first coils 14) and second wire 13 (the plurality of second coils 15).

### Method for Manufacturing Coil Device 100

Hereinafter, a method for manufacturing coil device 100 will be described.

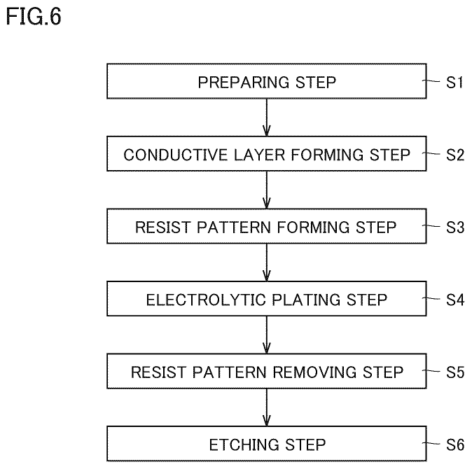

FIG. 6 is a diagram of a process for manufacturing coil device 100. As shown in FIG. 6, the method for manufacturing coil device 100 has a preparing step S1, a conductive layer forming step S2, a resist pattern forming step S3, an electrolytic plating step S4, a resist pattern removing step S5, and an etching step S6.

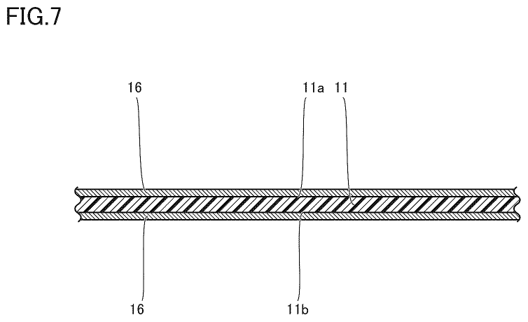

FIG. 7 is a cross sectional view illustrating preparing step S1. As shown in FIG. 7, in preparing step S1, base film 11 is prepared. In base film 11 prepared in preparing step S1, seed layer 16 is disposed on each of first main surface 11a and second main surface 11b.

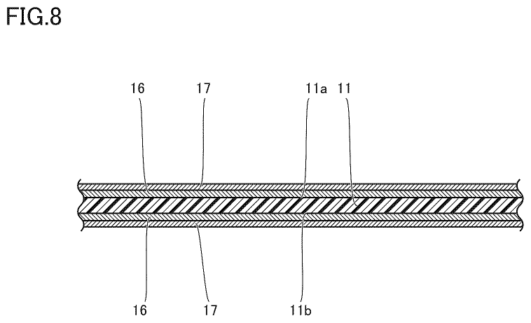

FIG. 8 is a cross sectional view illustrating conductive layer forming step S2. As shown in FIG. 8, in conductive layer forming step S2, for example, sputtering is performed to form conductive layer 17 on seed layer 16. It should be noted that, since through hole 11c is formed in base film 11 before conductive layer forming step S2 is performed, conductive layer 17 is also formed on the inner wall surface of through hole 11c and on the side surface of seed layer 16 contiguous to the inner wall surface of through hole 11c.

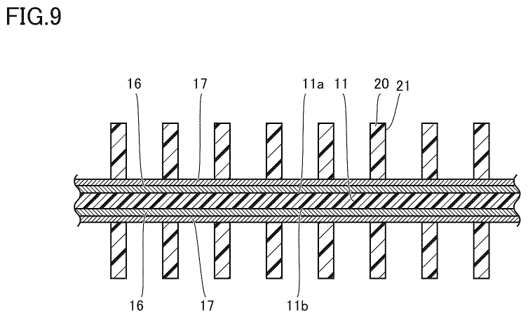

FIG. 9 is a cross sectional view illustrating resist pattern forming step S3. As shown in FIG. 9, in resist pattern forming step S3, a resist pattern 20 is formed on conductive layer 17. Resist pattern 20 has openings 21. Conductive layer 17 is exposed from openings 21. Resist pattern 20 is formed, for example, by attaching a dry film resist on conductive layer 17, and exposing the attached dry film resist to light and developing it.

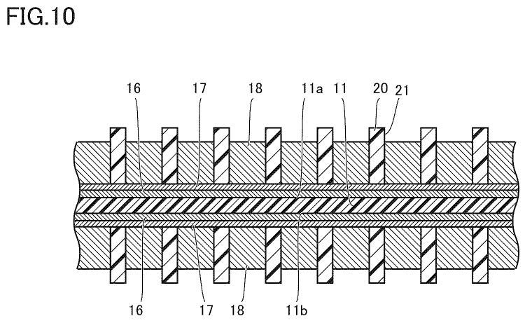

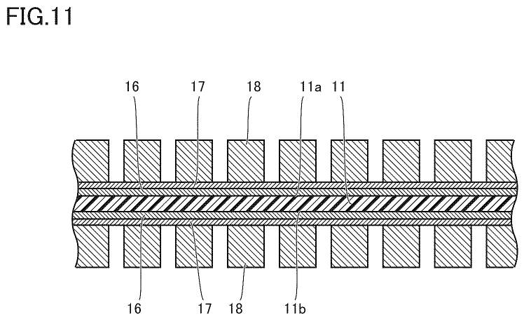

FIG. 10 is a cross sectional view illustrating electrolytic plating step S4. As shown in FIG. 10, in electrolytic plating step S4, electrolytic plating is performed to form electrolytic plating layer 18 on conductive layer 17 exposed from openings 21. FIG. 11 is a cross sectional view illustrating resist pattern removing step S5. As shown in FIG. 11, in resist pattern removing step S5, resist pattern 20 is removed.

In etching step S6, conductive layer 17 and seed layer 16 located under resist pattern 20 are removed by etching. In this manner, coil device 100 having the structure shown in FIGS. 1 to 3 is formed.

### Effects of Coil Device 100

Hereinafter, effects of coil device 100 will be described.

In coil device 100, since first wire 12 at first straight portion 14a and first wire 12 at second straight portion 14b extend along second direction DR2 in a plan view, thrust on a magnet increases, when compared with a case where an extending direction of first wire 12 at first straight portion 14a and an extending direction of first wire 12 at second straight portion 14b are inclined with respect to second direction DR2 in a plan view.

For the thrust of coil device 100, it is effective to increase the number of turns of first wire 12 constituting first coil 14. However, if first wire 12 is wound similarly at first straight portion 14a and second straight portion 14b, and at first connection portion 14c and second connection portion 14d, a dimension of first coil 14 in second direction DR2 increases, and thus a dimension of coil device 100 in second direction DR2 increases, as the number of turns of first wire 12 constituting first coil 14 is increased.

In coil device 100, first wire 12 constituting first coil 14 is wound such that the sum of width W3 and width W4 is smaller than the sum of width W1 and width W2. Accordingly, even when the number of turns of first wire 12 constituting first coil 14 is increased, an increase in the dimension of first coil 14 in second direction DR2 is suppressed. Thus, according to coil device 100, it is possible to suppress an increase in the dimension in second direction DR2 while improving the thrust on the magnet.

In a case where first wire 12 at first connection portion 14c and first wire 12 at second connection portion 14d extend along first direction DR1 in a plan view, width W3 and width W4 can be minimized, and thus it is possible to further suppress an increase in the dimension of coil device 100 in second direction DR2.

In a case where distance DIS1, distance DIS2, distance DIS3, and distance DIS4 are equal to each other, that is, in a case where the sum of width W3 and width W4 is made smaller than the sum of width W1 and width W2 by making width W7 and width W8 smaller than width W5 and width W6, resist pattern 20 has a constant pattern width, which facilitates formation and removal of resist pattern 20. Accordingly, in this case, first wire 12 can be easily formed.

In a case where coil device 100 has second wire 13 (the plurality of second coils 15), first coil 14 and second coil 15 overlapping each other function as one coil.

Accordingly, in this case, it is possible to further increase the thrust on the magnet.

### Second Embodiment

Hereinafter, a coil device according to a second embodiment will be described. The coil device according to the second embodiment is referred to as a coil device 200. Here, differences from coil device 100 will be mainly described, and redundant description will not be repeated.

### Configuration of Coil Device 200

Hereinafter, a configuration of coil device 200 will be described.

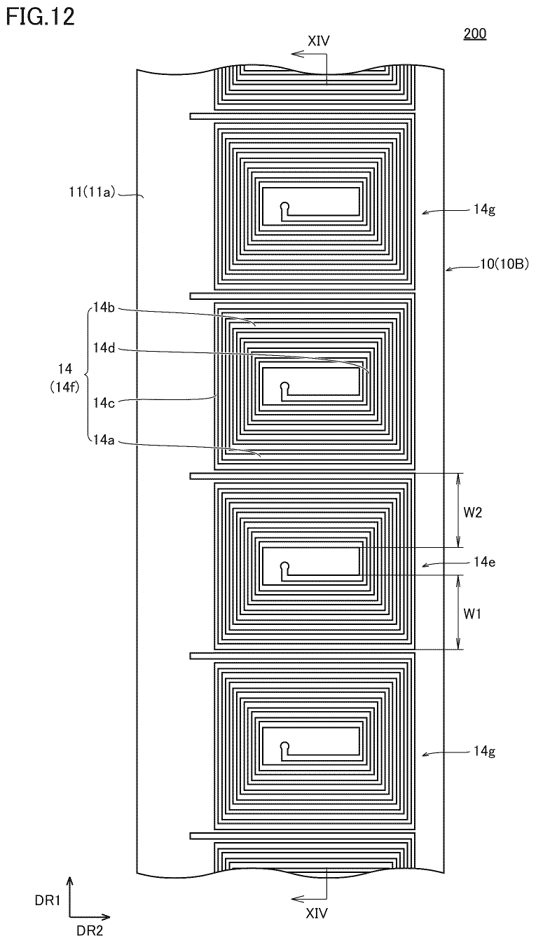

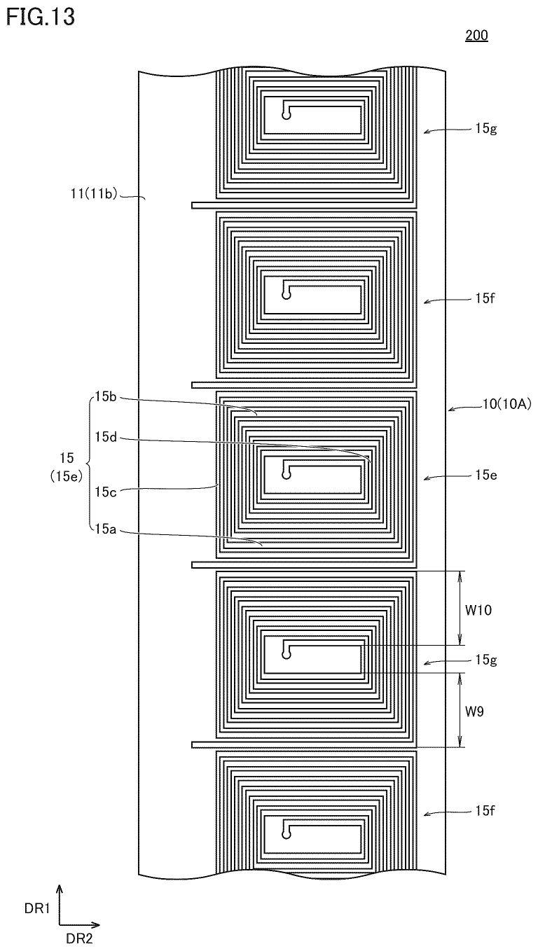

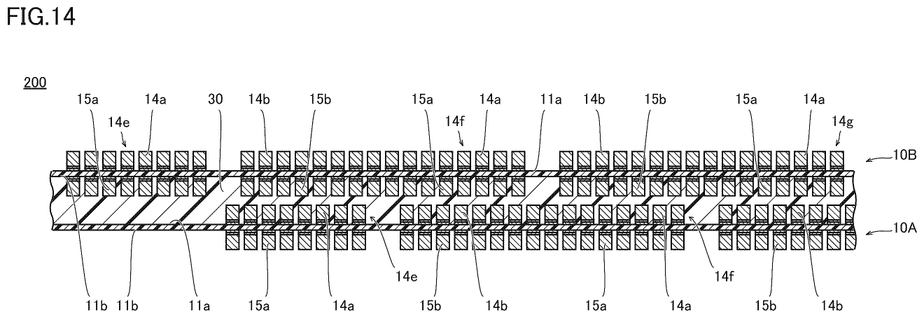

FIG. 12 is a first plan view of coil device 200. FIG. 13 is a second plan view of coil device 200. It should be noted that the direction of viewing the plane of FIG. 13 is the same as that of FIG. 12. FIG. 14 is a cross sectional view taken along XIV-XIV in FIG. 12. As shown in FIGS. 12 to 14, coil device 200 has a plurality of printed wiring boards 10. The number of the plurality of printed wiring boards 10 is preferably an even number. In the example shown in FIGS. 12 to 14, the number of the plurality of printed wiring boards 10 is two. These two printed wiring boards 10 are referred to as a printed wiring board 10A and a printed wiring board 10B. It should be noted that the number of the plurality of printed wiring boards 10 may be an even number of four or more.

First main surface 11a of printed wiring board 10A faces second main surface 11b of printed wiring board 10B. An adhesive layer 30 is interposed between printed wiring board 10A and printed wiring board 10B. Thereby, printed wiring board 10A and printed wiring board 10B are bonded to each other.

Printed wiring board 10A and printed wiring board 10B are disposed such that first straight portion 14a and second straight portion 14b of printed wiring board 10B respectively overlap second straight portion 14b and first straight portion 14a of printed wiring board 10A in a plan view. For example, first straight portion 14a of first coil 14e of printed wiring board 10B overlaps second straight portion 14b of first coil 14e of printed wiring board 10A, and second straight portion 14b of first coil 14e of printed wiring board 10B overlaps first straight portion 14a of first coil 14f of printed wiring board 10A.

### Modification

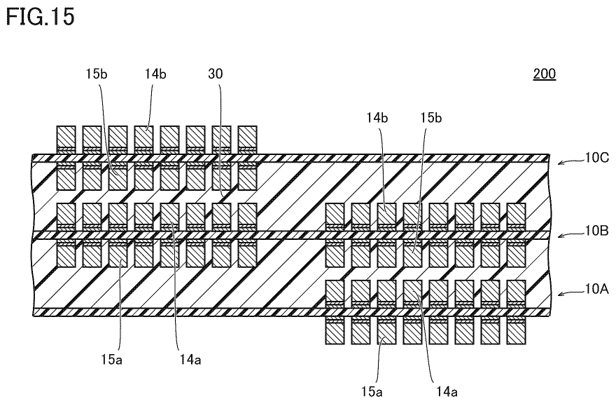

FIG. 15 is a cross sectional view of coil device 200 according to a modification. As shown in FIG. 15, the number of the plurality of printed wiring boards 10 may be an odd number. In the example shown in FIG. 15, the number of the plurality of printed wiring boards 10 is three. These three printed wiring boards 10 are referred to as printed wiring board 10A, printed wiring board 10B, and a printed wiring board 10C. However, the number of the plurality of printed wiring boards 10 may be an odd number of five or more.

First straight portion 14a of printed wiring board 10B underlies second straight portion 14b of printed wiring board 10C in a plan view. Second straight portion 14b of printed wiring board 10B overlaps first straight portion 14a of printed wiring board 10A in a plan view. Although not shown, first straight portion 14a of printed wiring board 10C overlaps second straight portion 14b of printed wiring board 10A in a plan view.

From another viewpoint, in a case where the number of the plurality of printed wiring boards 10 is an odd number, the spacing between two adjacent first coils 14 (second coils 15) is larger than that in a case where the number of the plurality of printed wiring boards 10 is an even number.

### Effects of Coil Device 200

In coil device 200, since first straight portion 14a and second straight portion 14b of printed wiring board 10B are disposed to respectively overlap second straight portion 14b and first straight portion 14a of printed wiring board 10A in a plan view, the coils can be disposed more closely along first direction DR1.

It should be understood that the embodiments disclosed herein are illustrative and non-restrictive in every respect. The scope of the present invention is defined by the scope of the claims, rather than the embodiments described above, and is intended to include any modifications within the scope and meaning equivalent to the scope of the claims.

### REFERENCE SIGNS LIST

10: printed wiring board; 10A: printed wiring board; 10B: printed wiring board; 10C: printed wiring board; 11: base film; 11a: first main surface; 11b: second main surface; 11c: through hole; 12: first wire; 13: second wire; 14: first coil; 14a: first straight portion; 14aa: first end portion; 14ab: second end portion; 14b: second straight portion; 14ba: third end portion; 14bb: fourth end portion; 14c: first connection portion; 14d: second connection portion; 14e, 14f, 14g: first coil; 15: second coil; 15a: third straight portion; 15aa: fifth end portion; 15ab: sixth end portion; 15b: fourth straight portion; 15ba: seventh end portion; 15bb: eighth end portion; 15c: third connection portion; 15d: fourth connection portion; 16: seed layer; 17: conductive layer; 18: electrolytic plating layer; 20: resist pattern; 21: openings; 30: adhesive layer; 100, 200: coil device; DIS1, DIS2, DIS3, DIS4, DIS5, DIS6, DIS7, DIS8: distance; DR1: first direction; DR2: second direction; S1: preparing step; S2: conductive layer forming step; S3: resist pattern forming step; S4: electrolytic plating step; S5: resist pattern removing step; S6: etching step; W1, W2, W3, W4, W5, W6, W7, W8, W9, W10, W11, W12, W13, W14, W15, W16: width.

1. A coil device comprising at least one printed wiring board, wherein
each of the at least one printed wiring board has a first base film having a first main surface and a second main surface opposite to the first main surface, and a first wire disposed on the first main surface,
the first wire has a plurality of first coil portions arranged along a first direction in a plan view,
each of the plurality of first coil portions is constituted by the first wire wound spirally in a plan view, and has a first straight portion and a second straight portion, and a first connection portion and a second connection portion,
in a plan view, the first wire at the first straight portion and the first wire at the second straight portion extend along a second direction orthogonal to the first direction,
the first straight portion has a first end portion and a second end portion which are both end portions in the second direction,
the second straight portion has a third end portion and a fourth end portion which are both end portions in the second direction,
the first connection portion connects the first end portion and the third end portion,
the second connection portion connects the second end portion and the fourth end portion, and
a sum of a width in the second direction of the first connection portion and a width in the second direction of the second connection portion is smaller than a sum of a width in the first direction of the first straight portion and a width in the first direction of the second straight portion.

2. The coil device according to claim 1, wherein, in a plan view, the first wire at the first connection portion and the first wire at the second connection portion extend along the first direction.

3. The coil device according to claim 2, wherein a width in the second direction of the first wire at the first connection portion and a width in the second direction of the first wire at the second connection portion are smaller than a width in the first direction of the first wire at the first straight portion and a width in the first direction of the first wire at the second straight portion.

4. The coil device according to claim 1, wherein a distance between two portions of the first wire adjacent to each other in the first connection portion and a distance between two portions of the first wire adjacent to each other in the second connection portion are less than or equal to a distance between two portions of the first wire adjacent to each other in the first straight portion and a distance between two portions of the first wire adjacent to each other in the second straight portion.

5. The coil device according to claim 2, wherein a distance between two portions of the first wire adjacent to each other in the first connection portion and a distance between two portions of the first wire adjacent to each other in the second connection portion are less than or equal to a distance between two portions of the first wire adjacent to each other in the first straight portion and a distance between two portions of the first wire adjacent to each other in the second straight portion.

6. The coil device according to claim 3, wherein a distance between two portions of the first wire adjacent to each other in the first connection portion and a distance between two portions of the first wire adjacent to each other in the second connection portion are less than or equal to a distance between two portions of the first wire adjacent to each other in the first straight portion and a distance between two portions of the first wire adjacent to each other in the second straight portion.

7. The coil device according to claim 1, wherein
each of the at least one printed wiring board further has a second wire disposed on the second main surface,
the second wire has a plurality of second coil portions arranged along the first direction in a plan view,
each of the plurality of second coil portions is constituted by the second wire wound spirally in a plan view, and has a third straight portion and a fourth straight portion, and a third connection portion and a fourth connection portion,
in a plan view, the second wire at the third straight portion and the second wire at the fourth straight portion extend along the second direction,
the third straight portion has a fifth end portion and a sixth end portion which are both end portions in the second direction,
the fourth straight portion has a seventh end portion and an eighth end portion which are both end portions in the second direction,
the third connection portion connects the fifth end portion and the seventh end portion,
the fourth connection portion connects the sixth end portion and the eighth end portion, and
a sum of a width in the second direction of the third connection portion and a width in the second direction of the fourth connection portion is smaller than a sum of a width in the first direction of the third straight portion and a width in the first direction of the fourth straight portion.

8. The coil device according to claims 1, wherein the at least one printed wiring board is a plurality of printed wiring boards.

9. The coil device according to claim 8, wherein
the plurality of printed wiring boards include a first printed wiring board and a second printed wiring board overlapping each other,
the second main surface of the second printed wiring board faces the first main surface of the first printed wiring board, and
the first straight portion of the second printed wiring board overlaps the second straight portion of the first printed wiring board in a plan view.
